(19) United States
(12) Patent Application Publication
(10) Pub. No.: US 2018/0074330 A1
(43) Pub. Date: Mar. 15, 2018

(54) Method And System For A Visual Overlay Display

(71) Applicant: Michael Callahan, San Francisco, CA (US)

(72) Inventor: Michael Callahan, San Francisco, CA (US)

(21) Appl. No.: 15/701,502

(22) Filed: Sep. 12, 2017

Related U.S. Application Data
(60) Provisional application No. 62/393,359, filed on Sep. 12, 2016.

(51) Int. Cl. G02B 27/01; H01L 51/44; B81B 3/00; G02C 7/04

(52) U.S. Cl. CPC G02B 27/0172; H01L 51/44; G06F 1/163; B81B 3/0027; G02C 7/04; B81B 3/0024

(57) ABSTRACT

Methods and systems for a visual overlay may include placing a visual display on a surface of an eye; generating energy in the visual display using one or more energy conversion devices in the visual display; and providing images to the eye via the visual display. Energy may be generated in the visual display via thermoelectric conversion, the conversion of mechanical energy using micro electro-mechanical system (MEMS) devices in the visual display, via reception of RF signals from a device external to the visual display, or conversion of visible light to electrical current. Energy in the visual display may be generated via electrochemical reactions with liquids on the surface of the eye. The visual display may comprise energy storage. Energy may be generated in the visual display via absorption of infrared radiation from the eye. The visual display may include a contact lens shape.

### CROSS-REFERENCE TO RELATED APPLICATIONS/INCORPORATION BY REFERENCE

This application claims priority to and the benefit of U.S. Provisional Application 62/393,359 filed on Sep. 12, 2016, which is hereby incorporated herein by reference in its entirety.

### TECHNICAL FIELD

Aspects of the present disclosure relate to displaying information. More specifically, certain implementations of the present disclosure relate to methods and systems for a visual overlay display.

### BACKGROUND

Conventional approaches for visual displays may be costly, cumbersome, and/or inefficient—e.g., they may be complex and/or time consuming.

Further limitations and disadvantages of conventional and traditional approaches will become apparent to one of skill in the art, through comparison of such systems with some aspects of the present disclosure as set forth in the remainder of the present application with reference to the drawings.

### BRIEF SUMMARY

System and methods are provided for a visual overlay display, substantially as shown in and/or described in connection with at least one of the figures, as set forth more completely in the claims.

These and other advantages, aspects and novel features of the present disclosure, as well as details of an illustrated embodiment thereof, will be more fully understood from the following description and drawings.

### BRIEF DESCRIPTION OF SEVERAL VIEWS OF THE DRAWINGS

FIG. 1 is a diagram illustrating a user with a visual overlay display, in accordance with an example embodiment of the disclosure.

FIG. 2 is a diagram illustrating power extraction in a visual overlay display, in accordance with an example embodiment of the disclosure.

FIG. 3 is a block diagram of a visual overlay display, in accordance with an example embodiment of the disclosure.

FIG. 4 illustrates a visual overlay display on a user's eye, in accordance with an example embodiment of the disclosure.

FIG. 5 illustrates a close-up cross-section of a visual overlay display in contact with an eye, in accordance with an example embodiment of the disclosure.

### DETAILED DESCRIPTION OF THE INVENTION

As utilized herein the terms “circuits” and “circuitry” refer to physical electronic components (i.e. hardware) and any software and/or firmware (“code”) which may configure the hardware, be executed by the hardware, and or otherwise be associated with the hardware. As used herein, for example, a particular processor and memory may comprise a first “circuit” when executing a first one or more lines of code and may comprise a second “circuit” when executing a second one or more lines of code. As utilized herein, “and/or” means any one or more of the items in the list joined by “and/or”. As an example, “x and/or y” means any element of the three-element set {(x), (y), (x, y)}. In other words, “x and/or y” means “one or both of x and y”. As another example, “x, y, and/or z” means any element of the seven-element set {(x), (y), (z), (x, y), (x, z), (y, z), (x, y, z)}. In other words, “x, y and/or z” means “one or more of x, y and z”. As utilized herein, the term “exemplary” means serving as a non-limiting example, instance, or illustration. As utilized herein, the terms “e.g.,” and “for example” set off lists of one or more non-limiting examples, instances, or illustrations. As utilized herein, circuitry or a device is “operable” to perform a function whenever the circuitry or device comprises the necessary hardware and code (if any is necessary) to perform the function, regardless of whether performance of the function is disabled or not enabled (e.g., by a user-configurable setting, factory trim, etc.).

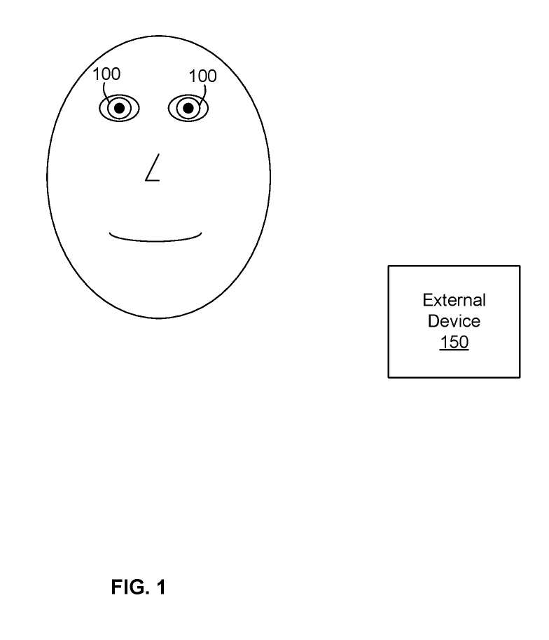

FIG. 1 is a diagram illustrating a user with a visual overlay display, in accordance with an example embodiment of the disclosure. Referring to FIG. 1, there is shown a user with visual overlay display 100 that may be in contact with or in close proximity to the user's eyes. The visual overlay display 100 allows for visual content to be placed within a minimal distance from the eye. This system may comprise a power source, a device, and visual content to be displayed. Other terms for such a device include ocular displays or augmentative displays. The overlay visual display 100 may communicate with an external device 150 for content delivery, for example, and as such may comprise a computer, smart phone, router, or server, for example.

The power source for the visual overlay display 100 may be self-contained within the display 100, in that it generates its own energy through means extracted from the user, user activity, or the environment, and may also receive power from an external source. One example is thermal energy harvesting, which is the conversion of heat, or a temperature difference, into electrical energy using thermoelectric generators. These rely on properties of a class of semiconductors known as thermoelectric materials, which create an electric potential when thermal energy migrates through them from a hotter side to a colder side. A contact lens-type structure may have thermoelectric conversion devices that generate electricity based on the heat of the eye.

In another embodiment, mechanical means may be utilized to harvest energy through the normal movement of the user and/or the movement of the eye within the eye socket. For example, micro-electro mechanical system (MEMS) devices may be integrated in the visual overlay display 100 that generate electrical current via a piezoelectric process.

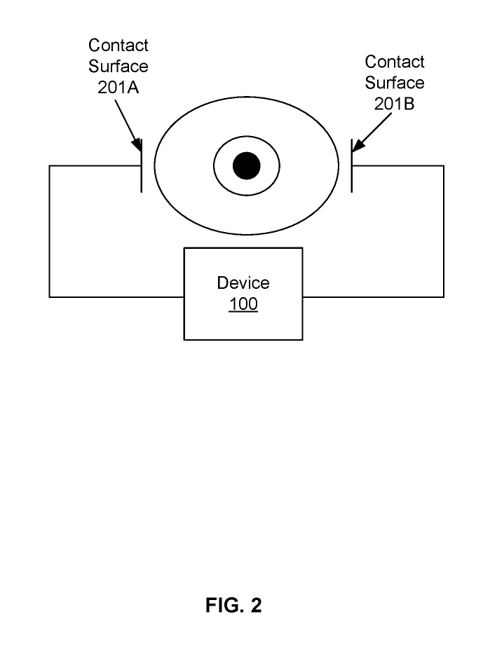

The power generation means may be placed in the visual overlay display 100 outside of the pupil of the user's eye, so as to avoid blocking visual information communicated to the user. The power source for the visual overlay display 100 is described further with respect to FIGS. 2-5.

FIG. 2 is a diagram illustrating power extraction in a visual overlay display, in accordance with an example embodiment of the disclosure. Referring to FIG. 2, there is shown visual overlay display 100 with contact surfaces that may be in contact with the user's eyes. The contact surface may enable the generation of power for the operation of the visual overlay display, either through thermal, chemical, and/or mechanical mechanisms, for example, although other mechanisms are possible.

Although FIG. 2 shows the contact surfaces 201A and 201B are shown on opposite sides of the eye, they may be on different sides of a contact lens type of structure, and may comprise a hydrogel material comprising ionic and/or non-ionic material, for example, such as used in contact lenses, with semiconductor layers sandwiched between.

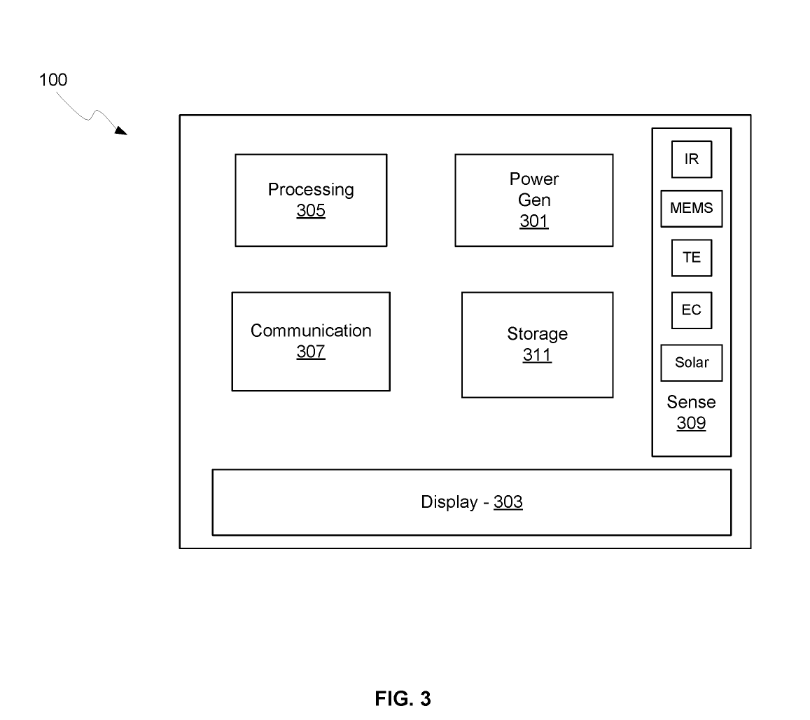

FIG. 3 is a block diagram of a visual overlay display, in accordance with an example embodiment of the disclosure. Referring to FIG. 3, there is shown visual overlay display 100 comprising a power generation module 301, display 303, processing module 305, communication module 307, sense module 309, and storage 311. In an example scenario, each of the modules shown in FIG. 3 may be integrated in a flexible circuit, such as organic semiconductors or ultra-thin semiconductors.

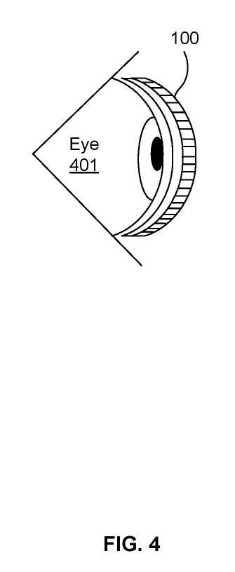

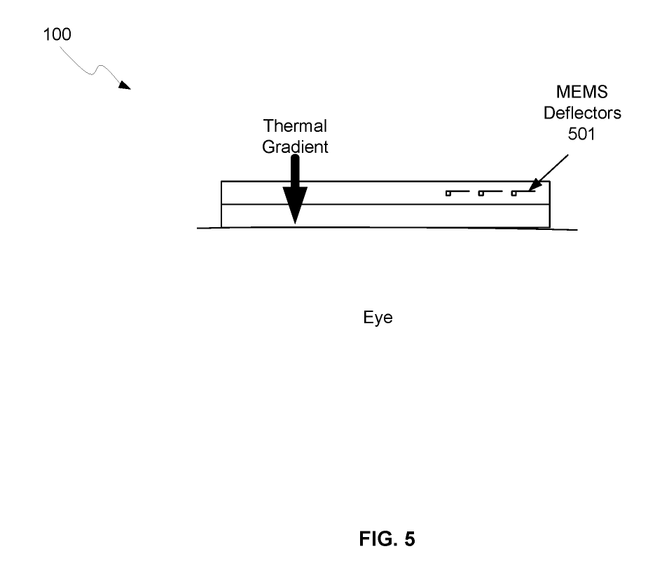

The power generation module 301 may comprise one or more energy harvesting technologies incorporated within, which are described further with respect to FIGS. 4 and 5. The power generation module 301 may also comprise energy storage capability, through integrated devices such as ultra-capacitors or ultra-thin battery-type structures. The sense module 309 may provide one or more inputs to the power generation module 301 for generating power for the visual overlay display 100. For example, the sense module 309 may comprise infrared (IR), mechanical (MEMS), thermoelectric (TE), electro-chemical (EC), or solar sensors for generating an electrical current to be provided to the power generation module 301.

The display 303 may comprise a flexible circuitry with light producers and/or modifiers, such as an array of light emitters for projecting an image on the user's retina, and may comprise transparent material to allow the user to also see through the device when desired. In another embodiment, the display 303 may comprise liquid crystals that may block light or allow it to transmit through the display 303, thereby providing visual information to the user. In addition, color filters over corresponding liquid crystal cells may enable color images and video.

The processing module 305 may comprise a processor for controlling the various circuitry in the visual overlay display 100. Depending on the technology of the flexible circuits, the processing module 305 may have more or less complexity. In an example scenario, the processing module 305 controls the communication module, saves and retrieves data from storage 311, configures the power generation module 301, and controls the display 303.

The power for the visual overlay display 100 may be generated via various mechanisms. For example, chemical processes may be utilized to generate energy to be used by the visual overlay display 100. One such example is ion solution, where a chemical solution in or near the eye, and/or optionally applied near the device creates charge carriers used to power the device. Inside the cell, optionally through a membrane on the sense module 309, for example, the chemical reaction itself takes place in the form of reduction or oxidation, releasing electrical energy. In this manner, chemical energy may be converted into electrical energy.

Another chemical energy generation method is through oxidation, where the process may be catalyzed or via natural oxidation of material (including both body fluids like blood and synthetic materials) to create charge carriers may be utilized to power the device. As the fluids are of course not unlimited in the human eye, it would likely be used in cooperation with other energy production processes. Similarly, ionization, either created or naturally occurring ionization may be used to power the visual overlay display 100. Finally, charge separation using water and hydrophilic material in the visual overlay display 100 may generate charge for providing power.

Another energy source is via communication of electrical energy. For example, wireless power may be transmitted to the visual overlay display 100. One such method is induction, using induction and/or inductive coupling to power the visual overlay display 100. In this technique, electromagnetic waves may be communicated to coils in the sense module 309 that then send current to the power generation module 301, where the current may be distributed to other circuitry in the visual overlay display 100 as needed, or stored if not needed.

In another scenario, capacitive coupling may be utilized, for example, to transfer energy to the visual overlay display 100, where an electric field may be generated externally, such as in a handheld wireless device, to power the visual overlay display 100. In another embodiment, electromagnetic signals, such as RF signals, for example, may be used to power the visual overlay display 100. In this embodiment, a transmitter may communicate RF signals to the communications module 307, for example, which may rectify the received RF signal for a DC voltage, and/or an unrectified signal may be utilized to charge an energy storage device, such as a battery or capacitor.

Another electrical option is through direct connection to an external source—where, through a physical connection, power may be delivered to the visual overlay display 100. A physical connection may comprise very thin insulated wires with enough slack in them to allow normal eye movements.

Another energy source for the visual overlay display 100 is muscular energy, where energy delivered to nearby muscle groups during actions such as blinking or other eye movements may be utilized to power the device. In another scenario related to capturing muscle energy, mechanical energy of the movement of the eye, and thus the visual overlay display 100, may be transferred to MEMS devices in the sense module 309, which may generate electrical current using piezoelectric means, for example.

Solar energy may also be used to power the visual overlay display 100 through an integrated, or non-integrated solar cell, where light is converted into energy. An integrated solar cell may be transparent and simultaneously able to produce energy while transferring light. Solar cells can absorb energy from sunlight and/or indoor lighting, for example, that may be utilized to charge a battery and/or power circuitry in the visual overlay display 100.

Another type of energy generation is by quantum mechanical processes through applied quantum physics, such as manufactured quantum dots, capacitors from nanotubes, etc) to produce energy used to power the device. For example, quantum dots of an appropriate dimension and bandgap to absorb visible and/or infrared light, i.e., thermal energy, may generate power and/or modify light frequencies directly for the visual overlay display 100.

Another energy source for the visual overlay display 100 is through mechanical processes. For example, movement—by creating small mechanical systems (such as NEMS/MEMS) capable of rolling, pushing, rotating, vibrating, etc, mechanical energy may be converted into electrical energy used to power the visual overlay display 100. Furthermore, bending—created by the body from such mechanisms as blood pressure, temperature constriction and expansion, eye movements, and or the environment, may produce energy from materials such as memory material, for example, that may be used to power the visual overlay display 100.

Yet another method for power generation of the visual overlay display 100 is through biological processes. Energy may be created through biological processes such as metabolism (including sugar), photosynthesis, or other similar processes. In addition, organisms such as viruses or bacteria may be used to produce energy to power the visual overlay display 100 or energy that may be harnessed from another part of the body (respiration producing mechanical energy, mechanical or electrical energy from the heart, eye, etc.) to power the visual overlay display 100.

Thermal energy may also be utilized to power the visual overlay display 100. Using temperature gradients, thermal radiation, and/or other properties of temperature may produce energy used to power the device. For example, semiconductors, specifically flexible semiconductors, such as organic materials, with a bandgap, on the order of ˜0.1 eV absorb electromagnetic radiation in the temperature range of the human body, and therefore photodiodes tuned to that wavelength could generate electrical currents from the heat of the user.

In an example scenario, a hybrid approach may be utilized where multiple power source systems that may use different mechanisms (such as electrical and biological) are used to power the visual overlay display 100. Finally, radiation may be captured and converted to other forms of radiation to produce energy used to power the visual overlay display 100.

The mechanisms above may be used individually or combined in order to power the visual overlay display 100. The mechanisms above may be used to power the device directly or used in conjunction with a power storage device (like a battery) to power the visual overlay display 100. Portions of the energy to power the visual overlay display 100 may be used for generating light and/or modifying existing environmental light.

FIG. 4 illustrates a visual overlay display on a user's eye, in accordance with an example embodiment of the disclosure. Referring to FIG. 4, there is shown a user's eye 401 and the visual overlay display 100. In an example scenario, the visual overlay display 100 may be powered by chemical processes with moisture of the eye, mechanical motion of the eye or the user itself, or thermoelectric energy from the difference in temperature of the eye 401 and the environment, for example, although the disclosure is not so limited, as discussed above with respect to FIG. 3.

The visual overlay display 100 comprises a thin material with ability to be shaped to fit the eye. Using the power source discussed above, it has the ability to control its optical properties ranging from being transparent to opaque, and/or color. Using properties such as polarization, electrochromism, electroluminescence, photochromism, thermochromism, field emission, suspended particle, quantum dots, quantum tunneling, liquid crystals, organic/inorganic light emitting diodes, etc. the opacity and color may be selectively controlled across the visual field of the visual overlay display 100. The visual overlay display 100 may produce and/or filter light, and focus.

The opacity can be combined with color filters to produce a colored pixel. By controlling the optical properties of the visual overlay display 100, it has the ability to display visual content. Optionally the visual overlay display 100 has computational ability via the processor 301. The source of the visual content may be stored on the device or from a nearby system capable of communicating with the visual overlay display 100 (via wireless transmission technology and the communication module 307). The visual overlay display 100 optionally has a camera, and/or environmental/biological sensors. Using these sensors, the device can sense eye position or gaze via measured electrical potentials created during eye movement. Feedback from the sensors 309 (orientation, camera information, etc) and or wearer (head position, focal position, heart rate, information related to the wearer, etc) may also be used in determining the visual content to display.

Using the display capabilities of the visual overlay display 100, visual content can be displayed. The visual content for the display may be on the device itself, stored in the storage module 311, for example, or communicated from a nearby device.

The visual content can be monochromatic and/or polychromatic and may comprise personalized and/or non-personalized content. Orientation and eye information can be used to modify (change orientation, virtually rotate, for example) the visual content. Through this modification, the visual overlay display 100 may display three dimensional content, which may overlay both the environment and people (such as face and body modification).

Face and body modifications may be customizable overlays that track appropriately on a person that changes their appearance for people looking at them with the visual overlay display 100. These changes range from changes in color, to changes in size and form (weight reduction, height enhancement, larger or smaller anatomy such as eyes, nose, breasts, facial augmentation, reconstruction, etc).

FIG. 5 illustrates a close-up cross-section of a visual overlay display in contact with an eye, in accordance with an example embodiment of the disclosure. Referring to FIG. 5, there is shown a portion of the visual overlay display 100 in contact with an eye. A gradient, such as a thermal gradient from the temperature of the eye compared to the outer surface of the visual overlay, may be utilized to generate energy, such as through the Thermoelectric Effect, for example. The Thermoelectric Effect is actually encompasses the Seebeck effect, Peltier effect, and Thomson effect. The Seebeck and Peltier effects are different manifestations of the same physical process. A higher temperature at the eye as compared to the temperature of the environment may generate an electrical current when the portion of the visual overlay display 100 comprises a stack of dissimilar materials used in thermoelectric devices, typically comprising a PN junction.

In another example scenario, a chemical gradient, such as from the chemistry of tears of the eye as compared to a chemical solution within the visual overlay display 100 may generate charge for powering the device. When separated by a membrane, this chemical gradient may cause a current to flow. Ions carry an electric charge that forms an electric potential across a membrane. If there is an unequal distribution of charges across the membrane, then the difference in electric potential generates a force that drives ion diffusion until the charges are balanced on both sides of the membrane.

Furthermore, FIG. 5 illustrate a simplified MEMS structure for harvesting mechanical energy. The visual overlay display 100 comprises one or more arrays of MEMS deflectors comprising a thin structure with a wider, and possibly thicker, end that is suspended over a cavity in which the deflectors 501 may be actuated by motion of the eye or the user. The MEMS deflectors may comprise piezoelectric material and therefore generate an electrical current when deflected.

In an example embodiment of the disclosure, a method and system is described for a visual overlay and comprises placing a visual display on a surface of an eye; generating energy in the visual display using one or more energy conversion devices in the visual display; and providing images to the eye via the visual display. Energy may be generated in the visual display via thermoelectric conversion, the conversion of mechanical energy using micro electro-mechanical system (MEMS) devices in the visual display, via reception of RF signals from a device external to the visual display, or conversion of visible light to electrical current. Energy in the visual display may be generated via electrochemical reactions with liquids on the surface of the eye. The visual display may comprise energy storage. Energy may be generated in the visual display via absorption of infrared radiation from the eye. The visual display may comprise a contact lens shape.

While the present invention has been described with reference to certain embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiment disclosed, but that the present invention will include all embodiments falling within the scope of the appended claims.

What is claimed is:

1. A method for providing visual content, the method comprising:
placing a visual display on a surface of an eye;
generating energy in the visual display using one or more energy conversion devices in the visual display; and
providing images to the eye via the visual display.

2. The method according to claim 1, comprising generating energy in the visual display via thermoelectric conversion.

3. The method according to claim 1, comprising generating energy in the visual display via conversion of mechanical energy.

4. The method according to claim 3, comprising converting mechanical energy via micro electro-mechanical system (MEMS) devices in the visual display.

5. The method according to claim 1, comprising generating energy in the visual display via reception of RF signals from a device external to the visual display.

6. The method according to claim 1, comprising generating energy in the visual display via conversion of visible light to electrical current.

7. The method according to claim 1, comprising generating energy in the visual display via electrochemical reactions with liquids on the surface of the eye.

8. The method according to claim 1, wherein the visual display comprises energy storage.

9. The method according to claim 1, comprising generating energy in the visual display via absorption of infrared radiation from the eye.

10. The method according to claim 1, wherein the visual display comprises a contact lens shape.

11. A system for providing visual content to a user, the system comprising:
a visual display that is placed a surface of an eye;
circuitry in the visual display that generates energy using one or more energy conversion devices in the visual display; and
circuitry in the visual display for providing images to the eye.

12. The system according to claim 11, wherein the visual display is operable to generate energy in the visual display via thermoelectric conversion.

13. The system according to claim 11, wherein the visual display is operable to generate energy in the visual display via conversion of mechanical energy.

14. The system according to claim 11, wherein the visual display is operable to convert mechanical energy via micro electro-mechanical system (MEMS) devices in the visual display.

15. The system according to claim 11, wherein the visual display is operable to generate energy in the visual display via reception of RF signals from a device external to the visual display.

16. The system according to claim 11, wherein the visual display is operable to generate energy in the visual display via conversion of visible light to electrical current.

17. The system according to claim 11, wherein the visual display is operable to generate energy in the visual display via electrochemical reactions with liquids on the surface of the eye.

18. The system according to claim 11, wherein the visual display comprises energy storage.

19. The system according to claim 11, wherein the visual display is operable to generate energy in the visual display via absorption of infrared radiation from the eye.

20. A system for communication, the system comprising:
a contact lens-shaped visual display that is placed a surface of an eye;
circuitry in the visual display that generates energy using one or more energy conversion devices in the visual display; and
circuitry in the visual display for providing images to the eye.
